(19) United States
(12) Patent Application Publication
(10) Pub. No.: US 2003/0141512 A1
(43) Pub. Date: Jul. 31, 2003

(54) Semiconductor component and method for fabricating a semiconductor component

(76) Inventors: Georg Bruderl, Burglengenfeld (DE); Johannes Baur, Deuerling (DE)

Correspondence Address: LERNER AND GREENBERG, P.A., POST OFFICE BOX 2480, HOLLYWOOD, FL, 33022-2480, US

(21) Appl. No.: 10/356,782

(22) Filed: Jan. 31, 2003

(30) Foreign Application Priority Data
Jan. 31, 2002 (DE) 102 03 801.5

(51) Int. Cl. H01L 21/00

(52) U.S. Cl. 257/99

(57) ABSTRACT

A semiconductor component has a substrate and a semiconductor body that contains at least one nitride compound semiconductor and is arranged on a surface of the substrate. An electrically conductive masking layer with a predetermined mask structure is arranged between the substrate and the semiconductor body. The masking layer partly covers the surface of the substrate. Furthermore, the invention describes a method for fabricating such a semiconductor component.

### BACKGROUND OF THE INVENTION

Field of the Invention

The invention lies in the semiconductor technology field. More specifically, the invention pertains to a semiconductor component having an electrically conductive substrate and a semiconductor body, which contains at least one nitride compound semiconductor and which is arranged on a surface of the substrate. The invention also pertains to a method for fabricating a semiconductor component having a substrate and a semiconductor body, which contains at least one nitride compound semiconductor and is arranged on a surface of the substrate.

Semiconductor components of the afore-mentioned type have a substrate and a semiconductor body containing a nitride compound semiconductor. The body is disposed on a surface of the substrate. A vertically conductive structure, wherein the operating current flows through the semiconductor body and the substrate, is advantageous with regard to the contact arrangement. This requires, inter alia, an electrically conductive substrate. With this arrangement, the contacts can be arranged in a simple manner on a main area of the semiconductor body and a main area of the substrate opposite to the main area, so that a homogeneous current flow is produced through the semiconductor body.

For semiconductor components based on a nitride compound semiconductor such as GaN, AlGaN, InGaN or AlInGaN, for example, an electrically conductive SiC substrate is often used, on which a plurality of semiconductor layers are grown epitaxially in order to form the semiconductor body.

The epitaxy requires a matching of the lattice constants of the epitaxy substrate and the semiconductor layer that is to be grown thereon. In the case of an SiC substrate, for this purpose, firstly a buffer layer may be applied to the substrate before the nitride compound semiconductor layer is grown. The buffer layer should have, in addition to the matched lattice constant, a good wetting of the SiC substrate. AlGaN, in particular, is suitable as material for the buffer layer. However, an AlGaN layer with a high Al content or an AlN layer which has a high electrical resistance or is even electrically insulating forms when an AlGaN buffer layer is grown on the substrate surface. This is known for example from Vennegues and Lahreche, Applied Physics Letters, Vol. 77, No. 26, pp. 4310-12. The electrical resistance of a vertically conductive structure is considerably increased as a result.

As an alternative, the buffer layer used may be a GaN buffer layer, which, however, forms a defect-rich layer with low electrical conductivity on account of the comparatively poor lattice matching to silicon carbide in the vicinity of the substrate surface.

On account of the low electrical conductivity caused by such buffer layers, corresponding semiconductor components have a high series resistance or a high forward voltage, as a result of which the efficiency of the component decreases. Moreover, as the conductivity of the buffer layer decreases, the risk of damage to the component is increased through the heat loss that arises.

### SUMMARY OF THE INVENTION

It is accordingly an object of the invention to provide a semiconductor component and a method for fabricating such a semiconductor component which overcomes the above-mentioned disadvantages of the heretofore-known devices and methods of this general type and which provides for an improved transition between the semiconductor body and the substrate. In particular, the intention is for such a semiconductor component to have an electrical series resistance that is as low as possible.

With the foregoing and other objects in view there is provided, in accordance with the invention, a semiconductor component, comprising:

an electrically conductive substrate having a surface;

a semiconductor body disposed on the surface of the substrate and containing at least one nitride compound semiconductor;

an electrically conductive masking layer between the substrate and the semiconductor body, the masking layer having a predetermined mask structure for reducing an electrical series resistance of the semiconductor component, and the mask structure partly covering the surface of the substrate.

In other words, provision is made for forming a semiconductor component having an electrically conductive substrate and a semiconductor body containing at least one nitride compound semiconductor, the body being arranged on a surface of the substrate, there being arranged between the semiconductor body and the substrate an electrically conductive masking layer with a predetermined mask structure, which partly covers the surface of the substrate. Preferably, the semiconductor component can be electrically contact-connected on that side of the substrate which is remote from the semiconductor body and at the semiconductor body.

The invention is based on the idea that, during the fabrication of the component, the semiconductor layers firstly grow in the regions of the substrate which are not covered by the masking layer, and the semiconductor layers subsequently grow together laterally to form a uniform semiconductor layer above the masking layer. In this case, in an advantageous manner, electrically nonconductive layers, for example for lattice matching, may also be arranged in the regions of the substrate which are not covered by the masking layer, since the electrically conductive masking layer electrically bridges such layers of low conductivity.

Preferably, the semiconductor body or one or more semiconductor layers of the semiconductor body are formed on the side facing the masking layer in such a way that the masking layer is at least partly embedded thereby. This embedding of the masking layer between the substrate and the semiconductor body leads to a further reduction of the series resistance and a uniform distribution of the operating current in the semiconductor body.

The electrically conductive substrate utilized herein is preferably a silicon carbide (SiC) substrate. As masking layer, it is possible, for example, to arrange a metal layer or an electrically conductive metal oxide layer on the substrate. The masking layer has a predetermined mask structure, for example in the form of a plurality of electrically conductive strips which are parallel or arranged in a lattice-like manner. A lattice-like arrangement has the arrangement of a particularly homogeneous current distribution in the semiconductor body. In the case of a strip arrangement, the individual parts which are not covered by the masking layer are extended further laterally, thereby facilitating the formation of a uniform semiconductor layer above the masking layer on account of the smaller number of interfaces.

In accordance with a preferred development of the invention, a buffer layer is formed in the regions not covered by the masking layer on the substrate surface. The buffer layer serves for lattice matching between subsequent layers of the semiconductor body and the substrate and, during the epitaxy, enables a transition that advantageously exhibits few defects between the semiconductor body and the substrate. In the case of the invention, the buffer layer can be embodied in an optimized manner with regard to the lattice matching and, in particular, may also be electrically poorly conductive or nonconductive since a possibly low electrical conductivity of the buffer layer is compensated for by the electrically conductive masking layer.

The invention is suitable in particular for radiation-emitting semiconductor components based on nitride compound semiconductors, such as, for example, light-emitting diodes (LEDs) or laser diodes. These components preferably comprise an n-conducting layer, for example an n-AlGaN, n-InGaN or n-AlInGaN layer, which adjoins the substrate or the masking layer, and also a p-conducting layer, for example a p-AlGaN, p-InGaN or p-AlInGaN layer, an active, radiation-emitting zone being formed between the n-conducting layer and the p-conducting layer. Said zone may contain InGaN, for example. Such component structures are distinguished by a high efficiency in the generation of radiation, the main emission wavelength being able to be set over a wide range through the material composition and/or the dimensioning of the semiconductor structure.

With the above and other objects in view there is also provided, in accordance with the invention, a method of fabricating a semiconductor component. The method comprises the following steps:

providing a substrate with a surface;

applying an electrically conductive masking layer to the substrate surface and forming a predetermined mask structure, to partly cover the substrate surface by the masking layer; and

applying at least one semiconductor layer of a semiconductor body on the substrate and on the masking layer, the semiconductor body containing at least one nitride compound semiconductor.

In other words, in the method according to the invention for fabricating a semiconductor component having a substrate and a semiconductor body arranged thereon, firstly a suitable substrate, for example an electrically conductive silicon carbide substrate, is provided and a masking layer with a predetermined mask structure is applied thereto.

Preferably, the masking layer is firstly formed as a continuous layer and subsequently patterned in accordance with the predetermined structure, so that the substrate surface is only partly covered by the electrically conductive masking layer. However, it is also possible to apply an already patterned mask to the substrate or to form the structure at the same time as the application of the masking layer.

Afterward, at least one semiconductor layer of the semiconductor body is applied to the substrate or the masking layer and the semiconductor body is then completed. The semiconductor layer is preferably deposited epitaxially on the substrate. In this case, at the beginning of the growth process, the semiconductor layer grows only into that region of the substrate surface which is not covered by the masking layer. (A slight coverage of the masking layer with semiconductor material is disregarded in this case). As soon as the semiconductor layer has exceeded the thickness of the masking layer, a lateral growth with a high rate of growth takes place and the masking layer is overgrown laterally by the semiconductor layer. This growth continues until the semiconductor layer is closed above the masking layer and a uniform semiconductor surface thus arises.

In accordance with an advantageous refinement of the invention, after the formation and, if appropriate, the patterning of the masking layer, a buffer layer is grown on the substrate and a semiconductor layer of the semiconductor body is subsequently deposited on the buffer layer. In particular, an AlGaN layer or an AlN layer is suitable for nitride compound semiconductors, the low electrical conductivity of such buffer layers advantageously being compensated for by the electrical conductivity of the masking layer.

The buffer layer is preferably deposited at a temperature which is as low as possible and which, in particular, is reduced in comparison with the temperature that is usually used to fabricate such buffer layers, in order to avoid a conversion of the material of the masking layer, for example into a metal-semiconductor compound.

Other features which are considered as characteristic for the invention are set forth in the appended claims.

Although the invention is illustrated and described herein as embodied in a semiconductor component and method for fabricating it, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of various specific embodiments when read in connection with the accompanying drawings.

### BRIEF DESCRIPTION OF THE DRAWINGS

FIG. 1 is a diagrammatic sectional view of a first exemplary embodiment of a semiconductor component according to the invention;

FIGS. 2A to 2E are diagrammatic illustrations of an exemplary embodiment of a fabrication method according to the invention using five intermediate steps;

FIG. 3 is a diagrammatic plan view of a second exemplary embodiment of a semiconductor component according to the invention; and

FIG. 4 is a diagrammatic plan view of a third exemplary embodiment of a semiconductor component according to the invention.

### DESCRIPTION OF THE PREFERRED EMBODIMENTS

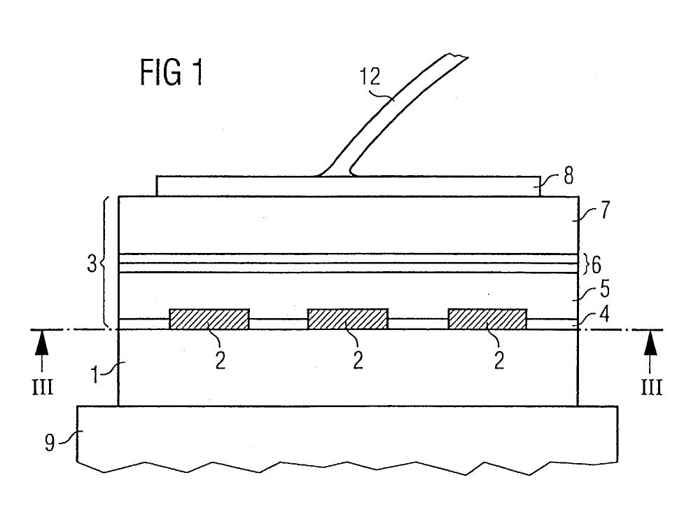

Referring now to the figures of the drawing in detail and first, particularly, to FIG. 1 thereof, there is shown a semiconductor component with a semiconductor body 3, which is comprised of a plurality of semiconductor layers 4, 5, 6 and 7 and is disposed on a substrate 1. The substrate, here, is an electrically conductive SiC substrate. The semiconductor layers form a radiation-emitting semiconductor structure based on GaN and typically contain compounds such as GaN, AlGaN, InGaN, InAlN, AlInGaN AlN, InN. By way of example, the layer 6 may be an active, radiation-generating InGaN layer or contain a radiation-generating structure such as, for example, a single or multiple quantum well structure with a plurality of InGaN layers.

The radiation-generating layer 6 is bordered by an n-conducting layer, for example an n-AlGaInN layer 5, on the side facing the substrate and by a p-conducting layer 7, for example a p-AlInGaN layer, on the opposite side.

An SiC substrate is suitable for fabricating such a structure by way of an epitaxy process, the deposition of a buffer layer on the SiC substrate being advantageous for the purpose of matching the lattice constant. For this purpose, in the exemplary embodiment shown, a lattice-like, electrically conductive masking layer 2 is formed on the substrate, which layer is covered and embedded by the semiconductor body 3. The buffer layer 4, for example an AlGaN layer, adjoining the substrate is applied to the substrate surface in the regions that are not covered by the masking layer. The semiconductor layers 5, 6 and 7 already described are arranged one after the other on the buffer layer 4. The buffer layer 4 is thinner than the masking layer 2.

This structural configuration has the advantage that the electrically conductive masking layer produces an electrical connection with high electrical conductivity between the substrate and the current-carrying layers of the semiconductor body. As a result, the buffer layer 4 itself can be optimized with regard to the lattice matching, a possibly associated deterioration in the conductivity on account of a high Al content, the formation of an AlN layer on the substrate surface or the formation of a defect-rich layer not significantly impairing the current transport between the substrate 1 and the semiconductor body 3.

A correspondingly patterned metal layer containing nickel, molybdenum and/or aluminum, for example, may serve as the masking layer 2. Generally, metals having a work function which is as low as possible and which is preferably less than the work function of the substrate, for example of the SiC substrate in the case of the exemplary embodiment described, are advantageous as material for the masking layer 2.

Furthermore, materials, in particular metals, having a high melting point (preferably greater than or equal to 800° C.) are suitable for the masking layer 2. Besides pure metals, the masking layer 2 may also contain metal alloys or metal compounds, in particular metal oxides such as, for example, indium oxide, tin oxide, zinc oxide or ITO (Indium Tin Oxide).

For contact connection purposes, the component is fixed on a suitable carrier 9 which is electrically conductive or has corresponding conduction structures on the mounting side for the substrate 1. Opposite to said carrier 9, the semiconductor body 3 is provided with a contact area 8, to which, by way of example, a wire connection 12 may be connected.

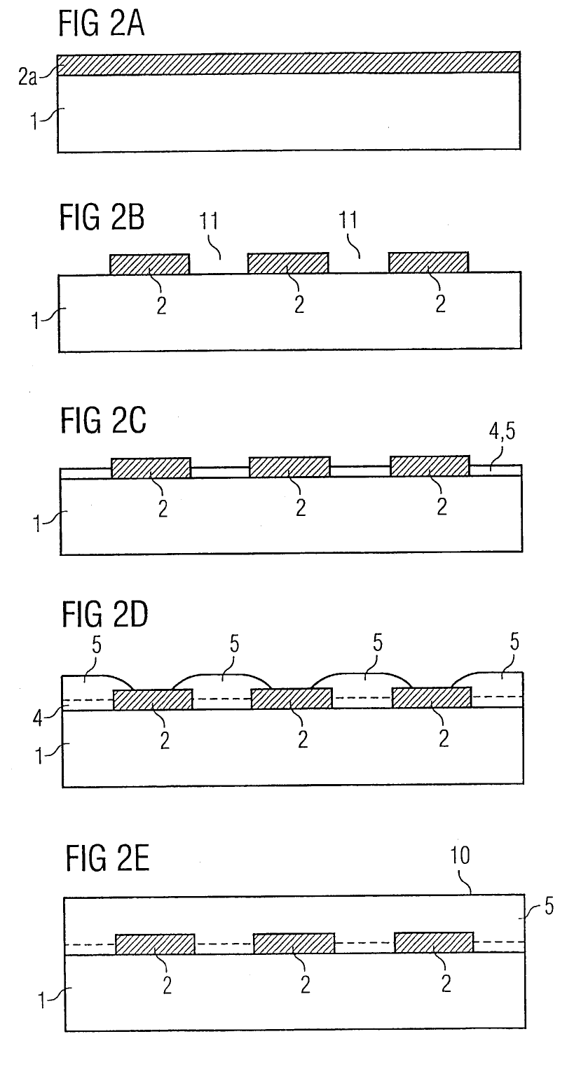

FIGS. 2A to 2E diagrammatically illustrate an exemplary embodiment of a fabrication method according to the invention using five intermediate steps.

In the first step, FIG. 2A, an electrically conductive, continuous layer 2a is applied to a substrate 1, for example an SiC substrate, the masking layer subsequently being formed from said layer. This may be a nickel layer or a layer made of one of the other metals or metal compounds already mentioned. The layer thickness of the masking layer preferably lies between 10 nm and 100 nm.

A conventional sputtering or vapor deposition method is suitable for the application of the layer 2a.

In the next step, FIG. 2B, the layer 2a is patterned, for example by means of a photolithography method, so that a masking layer 2 with openings 11 is produced on the substrate 1. The surface of the substrate 1 is thus uncovered at openings 11.

In the third step, FIG. 2C, the semiconductor body or at least one semiconductor layer 5 of the semiconductor body is applied. The layer 5 may be deposited epitaxially directly on the substrate 1 or optionally be grown on a buffer layer 4 that has been grown epitaxially beforehand. In this case, the layer 5 and, if appropriate, the buffer layer 4 grow initially only on the regions of the substrate 1 which are not covered by the masking layer 2, in other words the masking layer 2 is initially not covered.

A nitride-based semiconductor material, for example AlGaN, is preferably applied to the substrate in both cases. During the epitaxial deposition of such a semiconductor layer 5, an electrically insulating AlN film can form on the substrate 1. The application of a buffer layer 4 for lattice constant matching generally requires firstly the deposition of an Al-rich layer, which likewise has a low electrical conductivity. In the case of components according to the prior art, this would be associated with a great increase in the series resistance of the component. In the case of the invention, by contrast, said increase in the series resistance is compensated for by the electrical conductivity of the masking layer 2 since the masking layer 2 bridges poorly conducting layers between the semiconductor body and the substrate.

During the further growth of the semiconductor layer 5 beyond the thickness of the masking layer, the semiconductor layer 5 propagates in the lateral direction on account of the comparatively high lateral rate of growth, so that the masking layer 2 is overgrown by the semiconductor layer 5, FIG. 2D, and, finally, is completely embedded in the semiconductor layer 5. It has been shown that the epitaxial layer has a good crystal quality and, in particular, a low defect density in the regions which grow over the masking layer 2. Such overgrowth processes are also known by the name ELOG method (Epitaxial Lateral OverGrowth). The growth of the semiconductor layer 5 is continued until a uniform closed semiconductor surface 10 results above the masking layer 2. The result is illustrated in FIG. 2E.

The semiconductor layer 5 adjoining the substrate and/or the buffer layer 4 are preferably grown at a reduced temperature which is lower than the typical growth temperature for corresponding layers in conventional growth processes. The corresponding temperatures are known to those of skill in the pertinent art or can be gathered from the relevant literature. By way of example, an AlGaN layer is usually grown at temperatures of 1050° C. By contrast, in the case of the invention, the temperature is lowered to 950° C. in order to prevent the production of disadvantageous compounds comprising the material of the masking layer 2 and the substrate 1. In particular in the case of a masking layer which contains nickel, there is the risk of the formation of nickel silicide in the liquid phase, which makes the subsequent deposition of further layers more difficult.

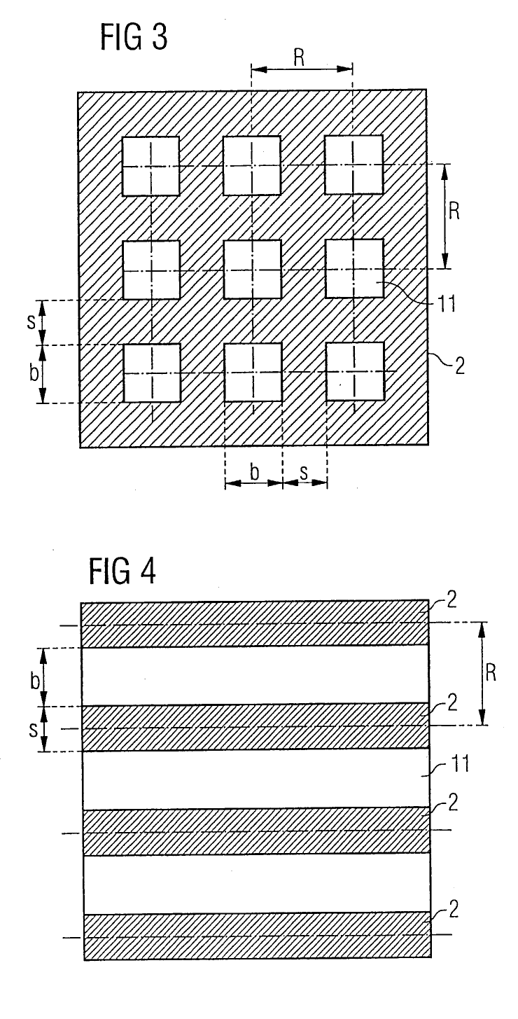

FIG. 3 shows a diagrammatic sectional view of a second exemplary embodiment of the invention. In the case of a component corresponding to FIG. 1, the section runs along the line III-III and shows the lateral structure of the masking layer 2.

The masking layer 2 is formed by a plurality of strips which cross one another perpendicularly and between which a plurality of square or rectangular openings 11 are formed. These openings correspond to the regions of the substrate which are not covered by the masking layer 2 and wherein the semiconductor layer 5 or the buffer layer 4 initially grows. The strip width s and the width b of the openings 11 preferably lies between 0.5 and 50 μm, particularly preferably between 1 μm and 20 μm. In this case, these dimensions or the grid dimension R=s+b can be adapted as required. By way of example, a square lattice with a strip width s of about 2 μm and a grid dimension R of about 5 μm has the advantage of a homogeneous current flow in the component. If the grid dimension R is increased, for example to 7 μm, given the same strip width s, then the layer thickness required to form a closed semiconductor layer decreases and the fabrication outlay thus decreases. With an even larger grid dimension, for example 12 μm, there is additionally an advantageous reduction of the dislocation density in the semiconductor layer.

A strip-type embodiment of the mask as is illustrated in FIG. 4 is possible as an alternative. In comparison with the variant shown in FIG. 3, here the semiconductor layer 5 is subdivided into a smaller number of individual regions, so that fewer interfaces abut one another during the overgrowth of the masking layer 2. This reduces the required layer thickness through to the formation of the uniformly closed semiconductor layer. The same range specifications as in the case of the exemplary embodiment shown in FIG. 3 are applicable to the strip width s, the opening width b and the grid dimension R=b+s, in the case of a strip-like arrangement the homogeneity of the current flow generally decreasing in favor of smaller required layer thicknesses and a lower dislocation density.

It will be understood that the foregoing description and the explanation of the invention by way of the exemplary embodiments does not, in any way, constitute a restriction of the invention thereto.

We claim:

1. A semiconductor component, comprising:
an electrically conductive substrate having a surface;
a semiconductor body disposed on said surface of said substrate and containing at least one nitride compound semiconductor;
an electrically conductive masking layer between said substrate and said semiconductor body, said masking layer having a predetermined mask structure for reducing an electrical series resistance of said semiconductor component, and said mask structure partly covering said surface of said substrate.

2. The semiconductor component according to claim 1, which comprises a contact connection on said substrate remote from said semiconductor body and a contact connection on said semiconductor body for electrically contact-connecting the semiconductor component.

3. The semiconductor component according to claim 1, wherein said substrate contains silicon carbide.

4. The semiconductor component according to claim 1, wherein said substrate essentially consists of silicon carbide.

5. The semiconductor component according to claim 1, wherein said masking layer contains a metallic material selected from the group consisting of a metal, a metal alloy, and a metal oxide.

6. The semiconductor component according to claim 1, wherein said masking layer contains at least one metal selected from the group consisting of nickel, molybdenum, aluminum, and zinc oxide.

7. The semiconductor component according to claim 1, wherein said masking layer contains at least one metal selected from the group consisting of nickel, molybdenum, aluminum, and n-conducting zinc oxide.

8. The semiconductor component according to claim 1, wherein regions of said substrate not covered by said masking layer and said masking layer are at least partly covered by said semiconductor body.

9. The semiconductor component according to claim 1, wherein said nitride compound semiconductor is a nitride compound of elements of at least one of the third and fifth main group of the periodic system of elements.

10. The semiconductor component according to claim 9, wherein said nitride compound semiconductor contains at least one compound selected from the group consisting of GaN, InH, AlN, AlGaN, InGaN, InAlN, and AlInGaN.

11. The semiconductor component according to claim 1, wherein said semiconductor body has a buffer layer adjoining said substrate in regions thereof not covered by said masking layer.

12. The semiconductor component according to claim 11, wherein said buffer layer contains one of AlN and AlGaN.

13. The semiconductor component according to claim 1, wherein said semiconductor component is a radiation-emitting component.

14. The semiconductor component according to claim 12, wherein said semiconductor component is a luminescence diode.

15. The semiconductor component according to claim 12, wherein said semiconductor component is one of a laser diode and a light-emitting diode.

16. The semiconductor component according to claim 11, wherein said semiconductor body has an n-conducting layer adjoining one of said substrate, said masking layer, and said buffer layer, and containing a nitride selected from the group consisting of AlGaN, InGaN, and AlInGaN, an active zone, and a p-conducting layer containing a nitride selected from the group consisting of AlGaN, InGaN, and AlInGaN.

17. The semiconductor component as claimed claim 16, wherein said active zone contains InGaN.

18. The semiconductor component according to claim 1, wherein said semiconductor body has an n-conducting layer adjoining one of said substrate and said masking layer and containing a nitride selected from the group consisting of AlGaN, InGaN, and AlInGaN, an active zone, and a p-conducting layer containing a nitride selected from the group consisting of AlGaN, InGaN, and AlInGaN.

19. A method of fabricating a semiconductor component, which comprises:
providing a substrate with a surface;
applying an electrically conductive masking layer to the substrate surface and forming a predetermined mask structure, to partly cover the substrate surface by the masking layer;
applying at least one semiconductor layer of a semiconductor body on the substrate and on the masking layer, the semiconductor body containing at least one nitride compound semiconductor.

20. The method according to claim 19, which comprises growing the semiconductor layer epitaxially, and initially growing the semiconductor layer primarily in regions on the substrate surface not covered by the masking layer.

21. The method according to claim 20, wherein the growing step comprises overgrowing the masking layer laterally during a growth of the semiconductor layer.

22. The method according to claim 21, which comprises growing the semiconductor layer to form a layer with a closed surface.

23. The method according to claim 21, which comprises growing the semiconductor layer to at least partly cover the masking layer with the semiconductor layer.

24. The method according to claim 19, wherein the step of applying at least one semiconductor layer comprises initially growing a buffer layer on regions of the substrate surface not covered by the masking layer.

25. The method according to claim 24, which comprises growing the buffer layer at a relatively reduced temperature.

26. The method according to claim 24, which comprises growing the buffer layer at a temperature less than or equal to 950° C.

27. The method according to claim 24, which comprises growing the buffer layer with one of AlN and AlGaN.
